(19) United States
(12) Patent Application Publication
(10) Pub. No.: US 2010/0226100 A1
(43) Pub. Date: Sep. 9, 2010

(54) MODULAR MULTIMEDIA MANAGEMENT AND DISTRIBUTION SYSTEM

(75) Inventors: Thomas J. Johnson, El Monte, CA (US); Thomas Henry Perszyk, Mason, OH (US)

Correspondence Address: LOZA & LOZA LLP, 305 North Second Ave., #127, Upland, CA, 91786-6064, US

(73) Assignee: YEN INTERNATIONAL, LLC, El Monte, CA (US)

(21) Appl. No.: 12/718,820

(22) Filed: Mar. 5, 2010

Related U.S. Application Data
(60) Provisional application No. 61/157,596, filed on Mar. 5, 2009.

(51) Int. Cl. H05K 5/00; H05K 7/00

(52) U.S. Cl. 361/730; 361/728

(57) ABSTRACT

Multimedia management devices comprise a plurality of multimedia management modules coupled together in an intermodular network. At least some of the multimedia management modules are adapted to distribute at least one of audio or video within an area. Each multimedia management module is configured to enable a distinct functionality to a multimedia management device. Each multimedia management module is sized and configured to be disposed at least partially within an electrical gang box.

### CLAIM OF PRIORITY UNDER 35 U.S.C. §119

The present application for patent claims priority to Provisional Application No. 61/157,596 entitled “Digital Audio-Video Wireless Mixer System” filed Mar. 5, 2009, the entire disclosure of which is hereby expressly incorporated by reference herein.

### FIELD

The present disclosure is directed to devices, systems and methods for managing various forms of multimedia.

### BACKGROUND

In recent years, classrooms, conference rooms and other areas are being setup with computers, displays, speakers and other communication means to enable the use of various forms of multimedia for enhancing and/or improving the learning and communication experience. Typically, one or more systems are employed for managing and interconnecting the various components of such communication means. Conventional systems often require separate installation for networking devices, audio devices, video devices and/or speakers.

Generally, such conventional systems are relatively large and typically require a large space in a room or area for storing the system. Often, in order to inhibit theft of such conventional systems, a large enclosure is set somewhere in the room, that may be locked when not in use. In order to access the system, the enclosure must be opened with a key. After using the system, the enclosure must again be closed and locked. If, for example, a teacher does not have access to the keys to the enclosure in a particular area, the system is not available for use.

One challenge for such large systems is to retrofit existing rooms with the new technology while minimizing installation labor. Conventionally, if a system were disposed into a wall, a special enclosure must be constructed and/or extensive modifications to room construction must be employed to retrofit the room. Furthermore, in order to upgrade features, conventional systems must generally be entirely replaced, which may also require a new custom enclosure and possibly additional modification to room construction.

Thus, a system is needed that facilitates installation, repair and replacement of all desired functions (e.g., networks, audio, video, etc.).

### SUMMARY

Various embodiments of the present disclosure are directed to multimedia management devices configured for easy installation into existing rooms, as well as repair, replacement and reconfiguration of various functions of the system. In one or more embodiments, a multimedia management device may comprise a plurality of multimedia management modules coupled together to form an intermodular network. At least some of the multimedia management modules of the plurality may be adapted to distribute at least one of audio and or video within a particular area. Each multimedia management module is configured to provide a distinct functionality to the multimedia management device, and each multimedia management module is sized and configured to be disposed at least partially within a conventional electrical gang box.

In at least one other embodiment, a multimedia management device may comprise a backplane sized and configured to be disposed within an electrical gang box. The backplane may include at least one module coupling feature and at least one intermodular network interface. One or more multimedia management modules may include an interface portion and a card portion. The interface portion may be sized and configured to be mechanically coupled to an electrical gang box. The card portion may include a backplane coupling feature mechanically and electrically coupled to the at least one module coupling feature of the backplane.

Other embodiments of the present disclosure relate to multimedia management assemblies. According to at least one embodiment, a multimedia management assembly may comprise an electrical gang box and a plurality of multimedia management modules. Each of the multimedia management modules may include an interface portion coupled to the electrical gang box and a card portion extending into the electrical gang box. The multimedia management modules of the plurality are communicatively coupled together. Each media management module of the plurality may be configured to be independently removed from the assembly without disabling the functionality of any remaining media management module.

Further embodiments of the present disclosure include multimedia management devices comprising a multimedia management module that is configured as a radio frequency receiver module. The radio frequency receiver module may be adapted to pair to a radio frequency transmitter using infrared to communicate pairing information between the radio frequency transmitter and the radio frequency receiver module. The radio frequency receiver module is further configured to receive audio data transmitted from the paired radio frequency transmitter using a first radio frequency band.

Yet another embodiment of the present disclosure includes multimedia management devices comprising a multimedia management module that is configured as a radio frequency transmitter module. The radio frequency transmitter module may be adapted to pair to a radio frequency receiver using infrared to communicate pairing information between the radio frequency receiver and the radio frequency transmitter module. The radio frequency transmitter module is further adapted to transmit audio data to the paired radio frequency receiver using a first radio frequency band.

### BRIEF DESCRIPTION OF THE DRAWINGS

FIG. 1 is a perspective view of an exemplary embodiment of a multimedia management device implemented in a classroom environment.

FIG. 2 is a front elevation view of a multimedia management device of FIG. 1.

FIG. 3 is an exploded view of a multimedia management device assembly according to at least one embodiment.

FIG. 4 is an isometric view of a multimedia management module according to at least one embodiment of the disclosure.

FIGS. 5A-5G illustrate various embodiments of multimedia management modules having different functionalities.

FIG. 5A is a front elevation view of a multimedia management module configured according to at least one embodiment of a volume control module.

FIG. 5B is a front elevation view of a multimedia management module configured according to at least one embodiment of an audio input module.

FIG. 5C is a front and side elevation view of a multimedia management module configured according to at least one embodiment of a video input module.

FIG. 5D is a front elevation view of a multimedia management module configured according to at least one embodiment of a remote control module.

FIG. 5E is a front elevation view of a multimedia management module configured according to at least one embodiment of a radio frequency receiver module.

FIG. 5F is a front elevation view of a multimedia management module configured according to at least one embodiment of a radio frequency transmitter module.

FIG. 5G is a front and side elevation view of a multimedia management module configured according to at least one embodiment of an external network interface module.

FIG. 6A is a front elevation view of a backplane according to at least one embodiment.

FIG. 6B is a rear elevation view of the backplane of FIG. 6A.

FIGS. 7A-7C illustrate various embodiments of backplanes including block diagrams representing circuitry which may be employed in each particular embodiment of a backplane.

FIG. 8 is an isometric view and an elevation view of a video receiver according to an embodiment of the present disclosure.

FIG. 9 illustrates a flow diagram for at least one embodiment of a method of assembling a multimedia management device.

FIG. 10 illustrates a flow diagram for an embodiment of an operational method of a multimedia management device including a radio frequency receiver module, a radio frequency transmitter module, or both.

### DETAILED DESCRIPTION

The illustrations presented herein are, in some instances, not actual views of any particular multimedia management module, system, or assembly, but are merely idealized representations which are employed to describe the present disclosure. Additionally, elements common between figures may retain the same numerical designation.

It is noted that the embodiments may be described in terms of a process that is depicted as a flowchart, a flow diagram, a structure diagram, or a block diagram. Although a flowchart may describe operational acts as a sequential process, many of these acts can be performed in another sequence, in parallel, or substantially concurrently. In addition, the order of the acts may be re-arranged. A process is terminated when its acts are completed. A process may correspond to a method, a function, a procedure, a subroutine, a subprogram, etc. Furthermore, the methods disclosed herein may be implemented in hardware, software, or both.

### Multimedia Management System

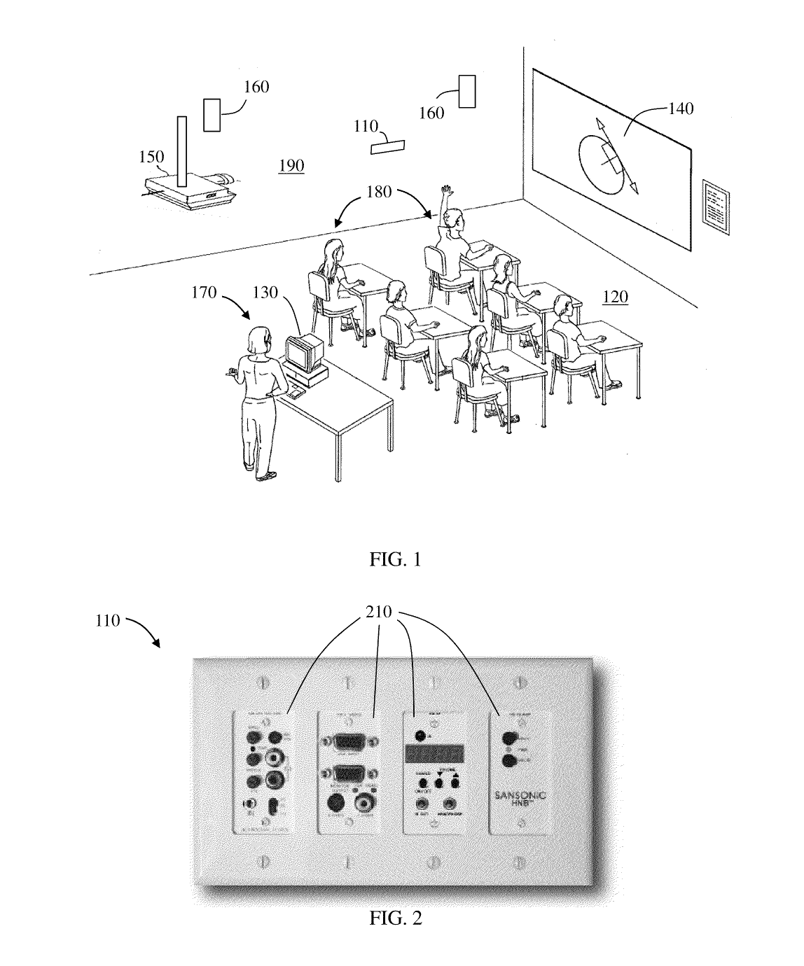

Various embodiments of the present disclosure comprise multimedia management systems for managing distribution of various forms of media, such as audio and video media. FIG. 1 illustrates one embodiment of a multimedia management device 110 associated with one or more area(s) 120 to manage various media components. For example, the multimedia management device 110 may be employed to enable computer 130 to display an image 140 through a projector 150 and/or to distribute audio content through speakers 160. Additionally, the multimedia management device 110 may enable one or more users, such as teacher 170 and students 180, to communicate using one or more microphones (not shown) through speakers 160. Area(s) 120 may comprise any areas wherein it may be desired or important to employ audio or visual communication throughout the area. By way of example and not limitation, area 120 may include a classroom, lecture hall, auditorium, boardroom, conference room, meeting hall, convention center, break-out area, briefing center, lobby, private office, theater backstage dressing room, green room, practice room, stadium skybox, concession stand, store, restaurant, salon, hospitality room, church multi-use area, church overflow area, surgery and recovery area, doctor's office, or healthcare administration area.

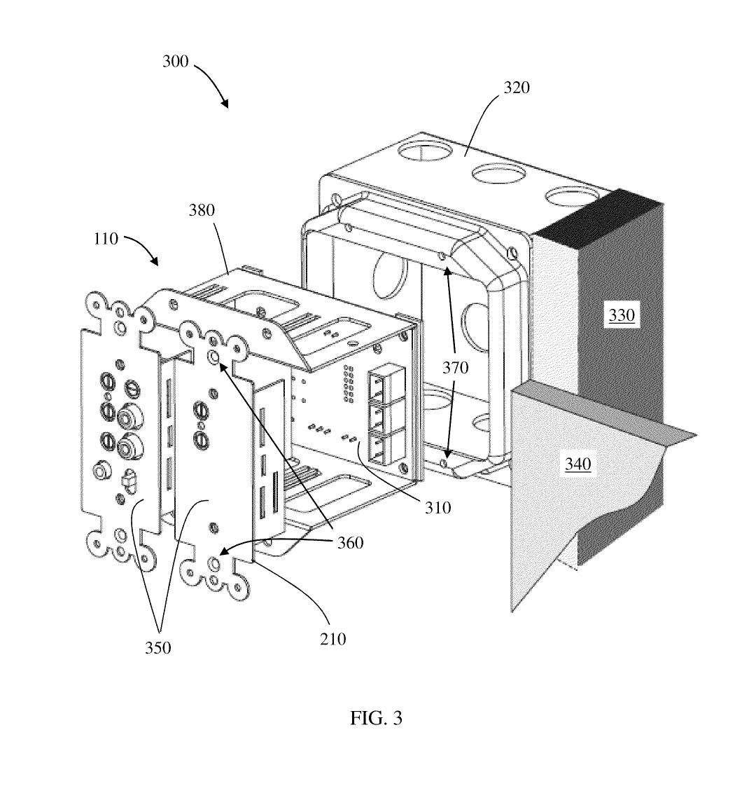

In various embodiments, one or more multimedia management devices 110 may be disposed in a wall 190 within area 120. The multimedia management device 110 may be implemented with various multimedia management modules in numerous configurations. FIG. 2 illustrates an embodiment of multimedia management device 110 of FIG. 1. As shown, the multimedia management device 110 may comprise one or more multimedia management modules 210 disposable within the wall 190 of area 120.

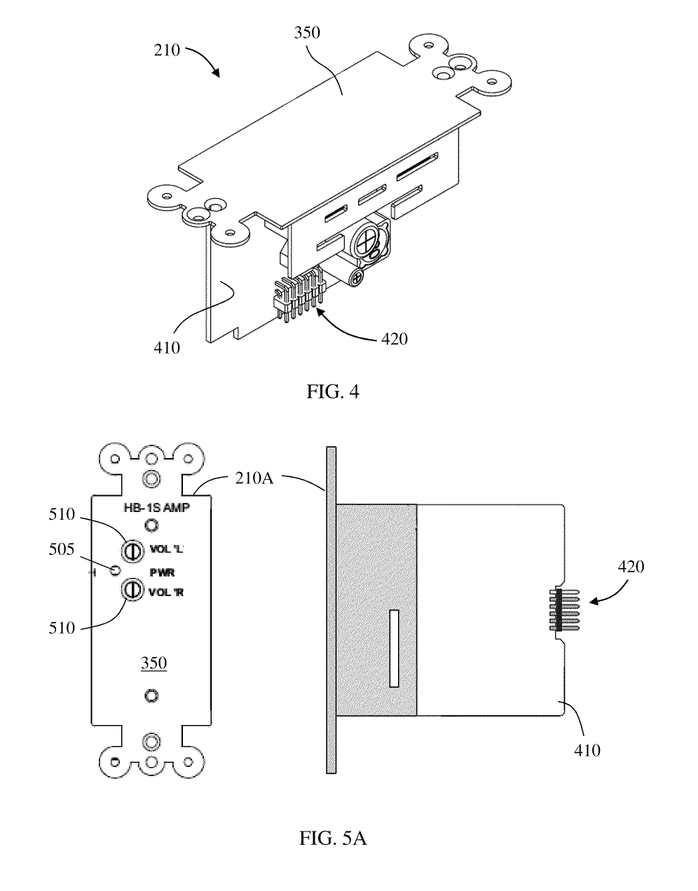

FIG. 3 illustrates an exploded view of a multimedia management assembly 300 according to at least one embodiment of the present disclosure. As illustrated, the multimedia management assembly 300 includes a multimedia management device 110 comprising at least one multimedia management module 210 coupled to a backplane 310. In a recessed installation, at least a portion of the multimedia management module 210 and the backplane 310 are disposed within a conventional electrical gang box 320, which may be coupled to a stud 330 behind sheetrock 340 of a conventional wall 190. In other installations, the multimedia management module may be surface mounted instead.

Although the electrical gang box 320 illustrated in FIG. 3 is a two-gang electrical gang box, electrical gang box 320 may comprise any sized gang box known in the art. For example, the electrical gang box 320 may comprise a one-gang, two-gang, three-gang, four-gang, five-gang or six-gang electrical gang box. A conventional electrical gang box 320 may be between about 3.5-inches (8.89 cm) and 4-inches (10.16 cm) tall. The width of the electrical gang box 320 is at least partially dependent on the gang configuration (i.e., one-gang, two-gang, etc.) of the electrical gang box 320 and the particular manufacturer. An non-limiting example of a suitable two-gang electrical gang box may comprise a width of about 4-inches (10.16 cm). The depth (from the front to the rear) of the electrical gang box 320 may vary according to various embodiments. In at least some embodiments, the electrical gang box 320 may comprise a depth between about 3-inches (7.62 cm) and about 4-inches (10.16 cm). In at least one embodiment, the electrical gang box 320 comprises a depth of about 3.5-inches (8.89 cm).

Additionally, a single electrical gang box 320 may be employed in some embodiments, or multiple electrical gang boxes 320 may be employed in other embodiments. The electrical gang box 320 may comprise any conventional material, including plastic or metal. The electrical gang box 320 may further be sized according to conventional sizes.

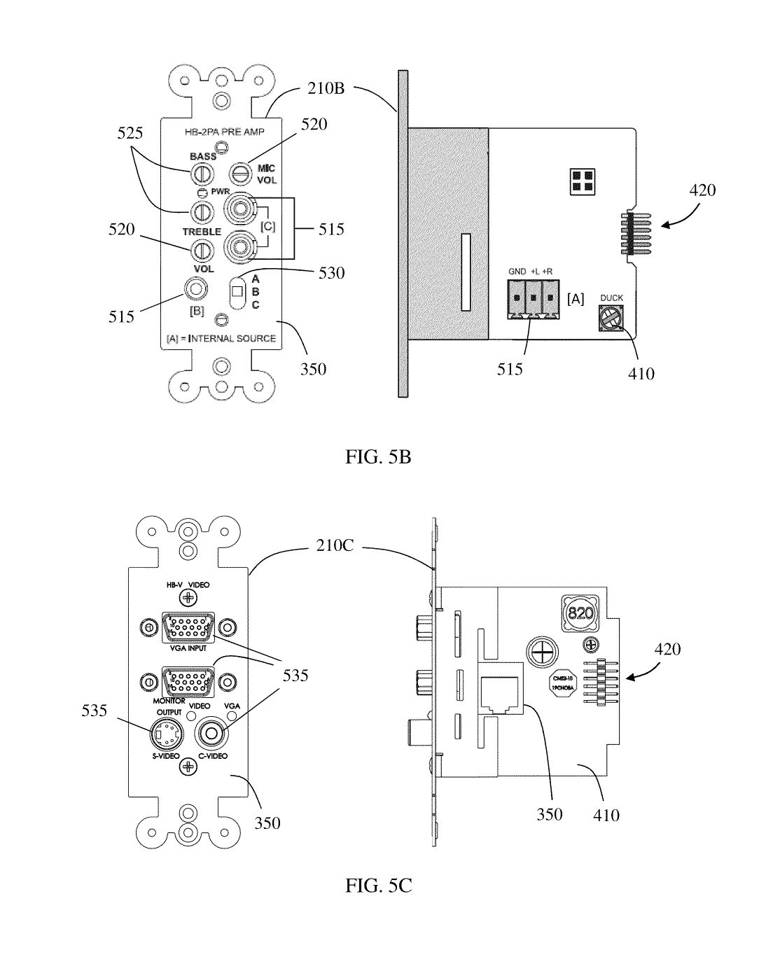

Referring still to FIG. 3, each multimedia management module 210 comprises an interface portion 350 that is configured for coupling to the electrical gang box 320. The interface portion 350 is configured to enable a user to utilize the functionality of each particular multimedia management module 210. In the embodiment shown, the interface portion 350 of each multimedia management module 210 comprises apertures 360 for receiving a fastener (not shown). The apertures 360 are located at the top and bottom (as oriented in FIG. 3) and configured to align with similar apertures 370 of the electrical gang box 320. Accordingly, the interface portion 350 may be coupled to the electrical gang box 320 in a manner similar to how a conventional light switch or power outlet would be attached to a conventional gang box 320. Each multimedia management module 210 also includes a card portion 410 (FIG. 4) extending into the electrical gang box 320 from adjacent the interface portion 350. The card portion 410 is substantially enclosed within the electrical gang box 320 when the interface portion 350 is coupled to the electrical gang box 320.

Positioned inside the electrical gang box 320 is a backplane 310. In some embodiments, the backplane 310 may be sized and configured to fit inside the electrical gang box 320 toward a rear portion thereof (the portion of the electrical gang box 320 that is opposite from where the interface portion 350 is coupled thereto). The backplane 310 is configured to be coupled to the card portion 410 of the multimedia management module 210. The backplane 310 may be disposed at least substantially parallel to a rear surface of the electrical gang box 320 to facilitate mechanically coupling the backplane 310 to one or more multimedia management modules 210. In some embodiments, the backplane 310 is attached to a bracket 380, which is configured to fit within the electrical gang box 320.

Because the multimedia management module(s) 210 and the backplane 310 are configured to fit substantially within and be coupled to a conventional electrical gang box 320, embodiments of the present disclosure are easily installed into existing areas 120 or easily incorporated by building designers into a new construction. In situations where an electrical gang box 320 is already installed in an existing area 120, originally installed components (e.g., light switches) in the existing electrical gang box 320 can be removed and replaced with various multimedia management modules 210.

Each of the multimedia management modules 210 is configured to provide different functionality to a multimedia management device 110 and to be communicatively coupled together to form a network of multimedia management modules 210. Accordingly, a multimedia management device 110 may be customized to a particular user's needs and specifications by adding or removing particular multimedia management modules 210. Each of the multimedia management modules 210 is configured to be installed into a multimedia management device 110 by simply inserting the particular multimedia management module 210 into the electrical gang box 310 and coupling the multimedia management module 210 to the other multimedia management modules 210 via a network of multimedia management modules 210. Similarly, a multimedia management module 210 may be removed from a multimedia management device 110 by simply decoupling the multimedia management module 210 from the network of multimedia management modules 210 and removing the decoupled multimedia management module 210 from the electrical gang box 320.

### Exemplary Multimedia Management Modules

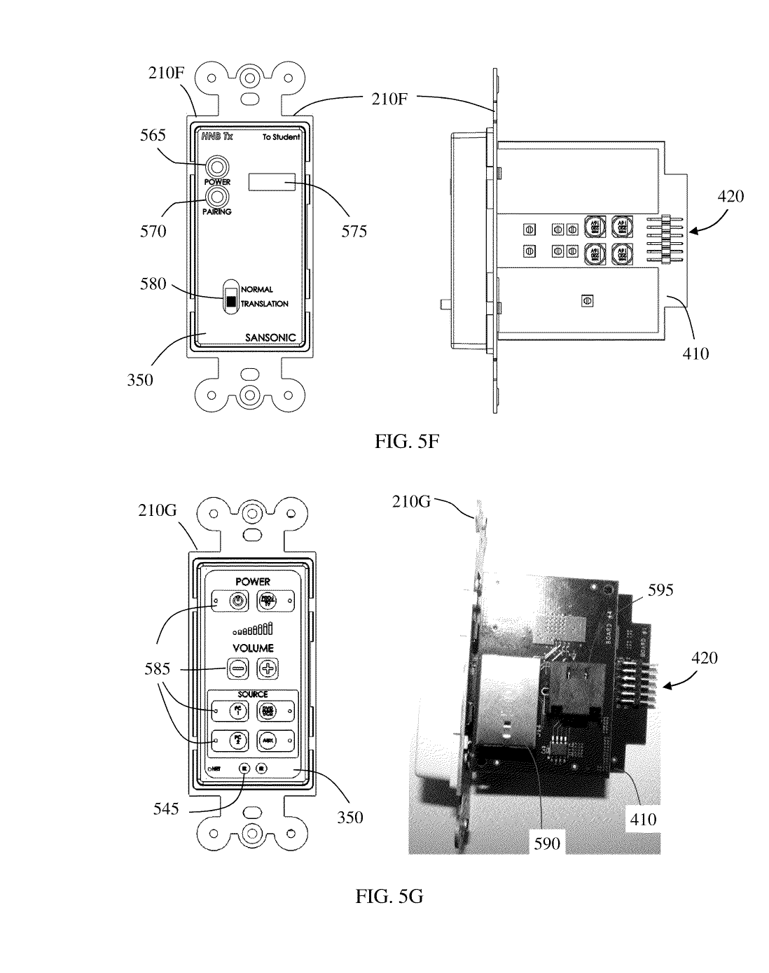

FIG. 4 is an isometric view of a multimedia management module 210 according to at least one embodiment. As noted above, each of the multimedia management modules 210 includes an interface portion 350 and a card portion 410. The card portion 410 of each multimedia management module 210 comprises various circuitry configurations and a backplane coupling feature 420. In at least some embodiments, the card portion 410 comprises at least one printed circuit board with circuitry, electronic devices or a combination thereof configured to carry out one or more particular functionalities. In at least some embodiments, the backplane coupling feature 420 of each card portion 410 may comprise a plurality of pins configured to be received by a multimedia management module coupling feature 610 (FIG. 6) of the backplane 310, described below. The plurality of pins may comprise twelve (12) total pins configured in two rows of six (6) pins each. Such a plurality of pins enables the card portion 410 to be both mechanically and electrically coupled to the backplane 310. In other embodiments, the backplane coupling feature 420 may comprise any conventional means for electrically coupling two electrical components together, such as wires, cables, traces of a printed circuit board, etc.

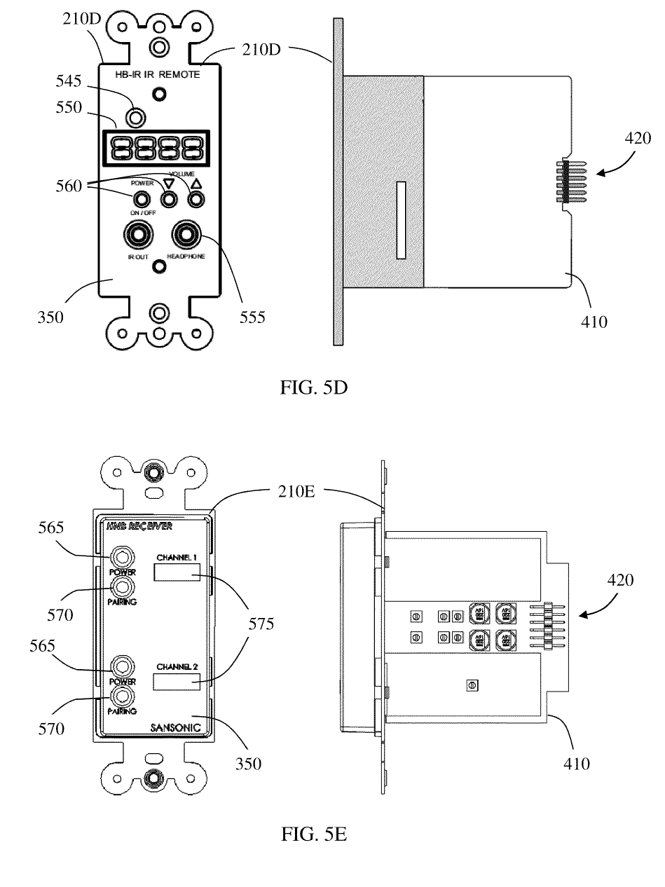

The various multimedia management modules 210 are each configured to provide a different functionality to a multimedia management device 110. FIGS. 5A-5G illustrate some non-limiting examples of various multimedia management modules 210 that may be utilized in embodiments of the present disclosure. FIG. 5A illustrates a front view of a multimedia management module configured as a volume control module 210A according to at least one embodiment. The volume control module 210A is configured to enable a user to adjust the volume in two different sets of audio transducers, such as left and right speakers. As shown, the interface portion 350 of the volume control module comprises a power indicator light 505 to inform a user that the volume controls are active, and left and right speaker volume controls 510 to enable a user to adjust the volume of any sound distributed through left and right audio transducers. According to at least some embodiments, the circuitry of the card portion 410 for the volume control module 210A may be coupled to one or more audio transducers and may comprise an amplifier circuit configured to enable the volume control module 210A to provide high fidelity stereo and mono audio to the one or more audio transducers.

FIG. 5B illustrates a front view of a multimedia management module configured as an audio input module 210B according to at least one embodiment. The functionality provided by the audio input module 210B includes enabling audio producing devices having various output characteristics to be coupled to the multimedia management device 110 so that the audio from the audio producing device can be distributed through one or more audio transducers coupled to the multimedia management device. The interface portion 350 of the audio input module 210B may include one or more audio inputs 515, dedicated volume controls 520 for one or more of the audio inputs 515 and sound shaping controls 525. In the embodiment illustrated, the interface portion 350 includes two audio inputs 515 labeled on the interface portion 350 as (B) and (C). The audio input 515 labeled as (B) is a standard 3.5 mm jack to which an audio player, such as an MP3 player (e.g., Microsoft ZUNE®, Apple iPOD®, etc.) or a CD player, may be coupled. The audio input 515 labeled as (C) is a standard RCA input. Another audio input 515 labeled as (A) is also provided on the card portion 410 of the audio input module 210B for use as a primary input from a wired or wireless microphone system. The audio input 515 labeled (A) may comprise a conventional phoenix input. An audio source selector 530 is provided on the interface portion 350 for enabling a user to select an audio source from among audio input 515 (A), (B) or (C) to be output to one or more audio transducers coupled to the multimedia management device 110.

FIG. 5C illustrates a front and side view of a multimedia management module configured as a video input module 210C according to at least one embodiment. The video input module 210C is configured to provide functionality relating to the distribution of images from an image generating device to one or more display devices. For example, the video input module 210C may enable a user to couple an image generating device such as a DVD player, Digital Video Recorder, cable or satellite tuner, laptop or desktop computer, etc. thereto, and to distribute image data from the image generating device to one or more display devices such as, for example, a television, monitor, projector, etc.

The interface portion 350 of the video input module 210C may include one or more conventional video inputs 535. By way of example and not limitation, the interface portion 350 of the video module 210C may comprise one or more VGA, composite video, S-video, HDMI, DVI, CCTV, F-type coax or component video input connectors, as well as combinations thereof, or any other conventional video input connector. In at least some embodiments, the card portion 410 of the video input module 210C may include a video network interface 540. The video network interface 540 is configured for coupling the video input module 210C to one or more display devices. By way of example and not limitation, the video network interface 540 may comprise a conventional network interface including, but not limited to, a RJ45, USB or FireWire connector.

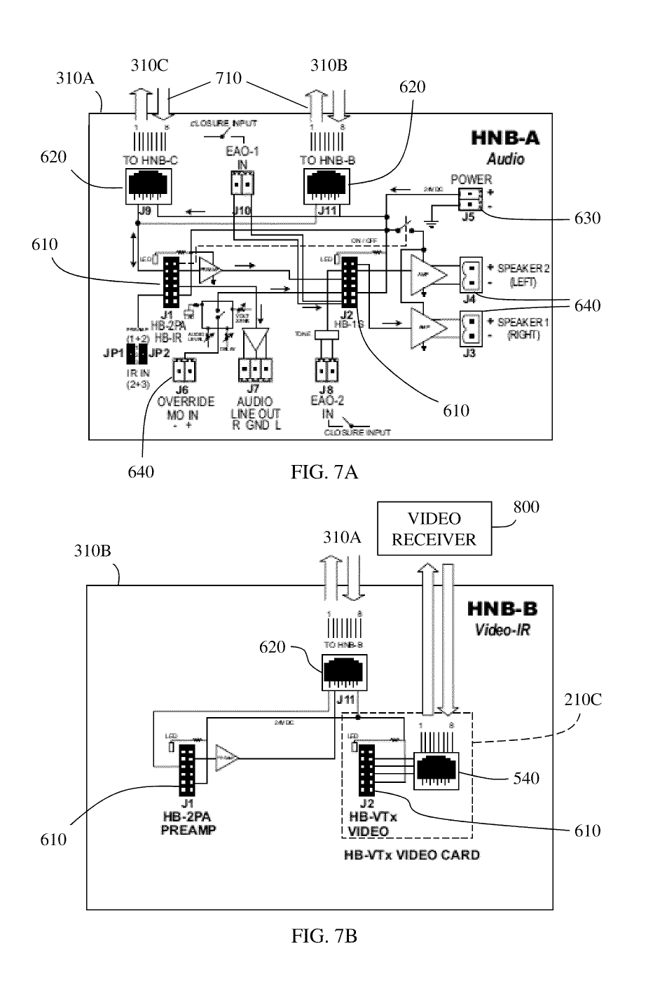

Because some display devices may not have compatible video network connectors (e.g. television, projector), a video receiver 800 may be coupled between the video input module 210C and the display device. As illustrated in FIG. 8, the video receiver 800 includes a video network interface 810 enabling the video receiver 800 to be coupled to, and receive image data from the video input module 210C. The video receiver 800 further includes one or more display device interfaces 820 for coupling to a display device. For example, a display device interface 820 may comprise one or more of a VGA, composite video, S-video or HDMI, DVI, CCTV, F-type coax or component video connectors.

Turning to FIG. 5D, a front view of a multimedia management module configured as a remote control module 210D is shown according to at least one embodiment. The remote control module 210D networked to one or more other multimedia management modules and configured to enable a user to control various functions of the one or more other multimedia management modules 210 using a remote controller unit (not shown). For example, the remote control module 210D may be networked and configured to enable a user to use a remote controller unit to control the power and volume of the volume control module 210A, select between inputs A, B and C for the audio input module 210B, mute all sound, as well as other controlling features of various multimedia management modules 210. For at least some embodiments, the interface portion 350 of the remote control module 210D may include an IR receiver 545 for receiving commands using IrDA (Infrared Data Association) communications from an IR remote controller unit. The interface portion 350 may further include a LED display 550, a 3.5 mm mini jack 555 for connecting headphones or other audio transducers, as well as soft push buttons 560 for enabling manual control of power and volume. The card portion 410 of the remote control module 210D comprises necessary circuitry for enabling control of the various other modules by infrared remote control.

FIG. 5E is a front view of a multimedia management module configured as a radio frequency receiver module 210E according to one or more embodiments. The radio frequency receiver module 210E is configured to enable a multimedia management device 110 to receive and utilize data transmitted by radio frequency. For example, the radio frequency receiver module 210E may be configured to receive audio data transmitted from one or more radio frequency microphones, and is networked to the volume control module 210A and/or the audio input module 210B for transmitting the audio data through one or more audio transducers coupled to the multimedia management device 110.

In at least some embodiments, the radio frequency receiver module 210E is configured to simultaneously receive radio transmissions for a plurality of different frequency bands, enabling the simultaneous use of at least two different transmitters (e.g., a teacher microphone and a student microphone) for a single area 120. In at least one embodiment, the radio frequency receiver module 210E is configured to simultaneously receive data transmissions using a first frequency band of 2.4 GHz and a second frequency band of 900 MHz.

Each frequency band of the plurality of frequency bands may employ two or more channels. As used herein, a “channel” refers to division of a frequency band in a manner to enable multiple users on the same frequency band without substantial interference. By way of example and not limitation, a frequency band may be divided by frequency slicing, time slicing, or any other conventional channel scheme as is known to a person of ordinary skill in the art. Some embodiments of the radio frequency receiver module 210E may be configured to employ a channel hopping scheme to reduce and even eliminate interference between adjacent areas 120 utilizing different multimedia management devices 110.

The card portion 410 of the radio frequency receiver module 210E comprises radio receiver circuitry to receive and demodulate data communicated wirelessly using a particular radio frequency band. The card portion 410 also includes an antenna for each of the plurality of frequency bands. Because the card portion 410 comprises the antenna for each frequency band, the antennas are fully enclosed within the electrical gang box 320 when a multimedia management device 110 is assembled.

The interface portion 350 of the radio frequency receiver module 210E may include a power button 565 for each frequency band and a pairing button 570 for each frequency band. Additionally, the interface portion 350 includes an IR sensor 575 associated with each frequency band. The IR sensor 575 enables infrared pairing of a transmitter and the radio frequency receiver module 210E prior to radio frequency data transmission. By using the IR sensor 575 for pairing, this forces line-of-site communications for pairing a transmitter (e.g., a microphone) to a receiver module 210E, thereby preventing an erroneous pairing with nearby transmitters and/or receivers. As used herein, pairing refers generally to the process in which the radio frequency receiver module 210E and a transmitter (e.g., a microphone) agree to communicate with each other and establish a connection. More particularly, the radio frequency receiver module 210E and the transmitter may identify one or more particular channels of the common frequency band on which to communicate and may establish the connection on the one or more channels. In some embodiments in which a channel hopping scheme is to be employed, the radio frequency receiver module 210E and the transmitter may also establish a channel hopping scheme for the radio frequency communications at part of the pairing process.

As noted, the pairing process utilizes infrared technology, IrDA (Infrared Data Association), to initially pair a transmitter with the radio frequency receiver module 210E. After the transmitter and the radio frequency receiver module 210E are paired by the infrared communications, the transmitter and the radio frequency receiver module 210E communicate by the identified channel(s) of the respective frequency band. In use, according to at least one embodiment, a user pushes the power button 565 of, for example, the first frequency band, that is to the left of the IR sensor 575 identified in FIG. 5E by the wording “channel 1.” Use of the terms “channel 1” and “channel 2” on the interface portion 350 of the radio frequency receiver module 210E in FIG. 5E refers to the two frequency bands and not to individual channels in a respective frequency band. Therefore, “channel 1” refers to the first frequency band and “channel 2” refers to the second frequency band. After turning on the power to the first frequency band and to the transmitter, the user pushes the pairing button 570 associated with the “channel 1” IR sensor 575 and a pairing button associated with the transmitter. The user then assures that the “channel 1” IR sensor 575 and a similar IR sensor of the transmitter are directed toward each other until the pairing is completed. In at least one embodiment, completion of the pairing process is indicated by a light on at least one of the radio frequency receiver module 210E or the transmitter. After the radio frequency receiver module 210E and the transmitter are paired, the user may commence wireless data transmission using the respective radio frequency band. A second transmitter may be paired to the second frequency band in a similar manner. In some implementations, as an additional security feature, once paired the transmitter (e.g., microphone) may not work or operate with another receiver module (e.g., a receiver module in another room) without first being paired to that another receiver module. Additionally, in some implementations, a transmitter may only be paired with one receiver module at any given time.

FIG. 5F illustrates a front view of a multimedia management module configured as a radio frequency transmitter module 210F. The radio frequency transmitter module 210F is configured to enable a multimedia management device 110 to transmit data by radio frequency. For example, the radio frequency transmitter module 210F may enable a multimedia management device 110 to receive audio data from, for example, the audio input module 210B or the radio frequency receiver module 210E, and transmit the audio data to one or more receivers (e.g., a wireless listening device, earphones).

In at least some embodiments, the radio frequency transmitter module 210F is configured to transmit data over a plurality of different radio frequency bands, enabling the simultaneous transmission of at least two different data streams for a single area 120 (e.g., teacher's original audio data from the teacher's microphone and language translation data from another microphone). By way of example and not limitation, the radio frequency transmitter module 210F according to at least one embodiment is configured to simultaneously transmit data transmissions using a first frequency band of 2.4 GHz and a second frequency band of 900 MHz, each frequency band including a plurality of channels. This may facilitate near real-time translation of speech from a first language to a second language, where some recipients may have headsets that receive the translated speech in the second language. In other implementations, a plurality of frequency bands or channels may be available to allow translation from one language to multiple languages. The card portion 410 of the radio frequency transmitter module 210F comprises radio transmitter circuitry to modulate and wirelessly transmit data using a particular radio frequency band. The card portion 410 also includes an antenna for each frequency band, each antenna being fully enclosed within the electrical gang box 320 when a multimedia management device 110 is assembled.

The interface portion 350 of the radio frequency transmitter module 210F may include a power button 565 and a pairing button 570, as well as an IR sensor 575, similar to the power and pairing buttons and IR sensor of the radio frequency receiver module 210E. The IR sensor 575 enables infrared pairing of a receiver to the radio frequency transmitter module 210F prior to radio frequency data transmission. Pairing is carried out in a similar manner as described herein above with relation to the radio frequency receiver module 210E.

The interface portion 350 further includes a transmission channel selector 580. In at least some embodiments, such as the embodiment shown in FIG. 5F, the transmission channel selector 580 may be selectable between a normal transmission mode and a translation transmission mode. In the normal transmission mode, the radio frequency transmitter module 210F is configured to wirelessly broadcast over a first frequency band any audio being input into the multimedia management device 110 via the audio input module 210B, any frequency band of the radio frequency receiver module 210E or both. A receiver may receive the audio wireless broadcast via the first frequency band and enable a user to listen to the audio, for example with headphones coupled to the receiver. In the translation transmission mode, the radio frequency transmitter module 210F may be configured to broadcast all the same input audio via the first frequency band except audio input via the second frequency band of the radio frequency receiver module 210E. Instead, all the audio data that is input via the second frequency band of the radio frequency receiver module 210E is directed exclusively to the second frequency band of the radio frequency transmitter module 210F. In this manner, a microphone coupled to the radio frequency receiver module 210E for data transmission via the second frequency band can be used in translation transmission mode for providing language translation to those receivers configured to receive transmissions or broadcasts on the second frequency band. In the translation transmission mode, the microphone coupled to the radio frequency receiver module 210E for data transmission via the second frequency band is inhibited from being distributed to the general audio transducers coupled to the multimedia management device 110. This allows an on-site or off-site translator to receive the audio input, translate the audio input (e.g., into a second language), and provide a translated audio signal via the second frequency band to those receivers configured to receive over the second frequency band.

FIG. 5G is a front and side view of an embodiment of a multimedia management module configured as an external network interface module 210G. The external network interface module 210G is configured to enable interconnectivity of the multimedia management device 110 with an external network, such as the internet, a virtual private network (VPN), a local area network (LAN), a wide area network (WAN), etc., for transferring multimedia data to or from the multimedia management device 110. The external network interface module 210G is enabled to obtain audio and/or visual media from the external network for distributing within a particular area 120, as well as to convey audio and/or visual media to another computer on the network.

By way of example and not limitation, the external network interface module 210G may be connected to a network through a conventional DHCP server and may be addressable by the external network. For example, the external network interface module 210G may comprise a unique MAC address enabling the external network interface module 210G to be individually addressable. With the external network interface module 210G configured to be individually addressable, the external network is able to route different data streams to different external network interface modules 210G in different areas 120, facilitating audio and/or video data to be specifically routed to a particular area 120 or to a particular multimedia management device 110. Furthermore, with the external network interface module 210G configured to be individually addressable, one or more multimedia management modules 210 of a multimedia management device 110 may send data audio/video streams to a remote location via the external network.

By way of example and not limitation, a multimedia management device 110 may be employed in a classroom of a school. The external network interface module 210G may enable an administrator to convey audio and/or video data from a central location to each multimedia management device 110 over a network so that each selected classroom can view and/or hear a particular event. In another implementation, audio and/or video data may be conveyed from a multimedia management device 110 in an originating classroom to a computer in a remote classroom over the network, enabling one or more students in the remote classroom to participate in the activities of the originating classroom.

The interface portion 350, according to some embodiments, may include soft buttons 585 for various functions including power control, projector/TV power, volume control, audio and video source selection, etc. At least some of the soft buttons may be user configurable and adaptable or programmable to alternate functions according to a user's preference. The card portion 410 of the external network interface module 210G may include an external network interface 590. The external network interface 590 may comprise any known interface for connecting a data transfer cable. By way of example and not limitation, the external network interface 590 may comprise one of a RJ45, USB or FireWire connector.

In some embodiments, the external network interface module 210G enables additional functionalities through software operating on a remote computer. By way of example and not limitation, a software program may be implemented on a remote computer to combine a plurality of areas 120 for distribution of the audio and/or visual media from a single source within the plurality of areas 120. For example, in a school setting, an administrator may implement software from a central computer causing media to be distributed to two or more areas 120 from a single source, such as a microphone in one area 120. In this manner, a person invited to speak to a class of, for example, sixth-grade students in one classroom, can have the audio conveyed in real-time to all other sixth-grade classrooms accessible by the network. More specifically, and by way of a non-limiting example, the software program may cause audio data received in one classroom through the radio frequency receiver module 210E (e.g. coupled to a wireless microphone) to be conveyed over the network from the external network interface module 210G in the original classroom to the external network interface module 210G of each of the other specified classrooms. The external network interface module 210G of each of the other specified classrooms then conveys the audio data to, for example, the audio input module and/or the volume control module, and then to one or more audio transducers in the other specified classrooms.

In some embodiments of the external network interface module 210G, a video module network interface 595 may be included on the card portion 410 to enable the external network interface module 210G to be directly coupled to the video input module 210C. In such embodiments, the video input module 210C may also include a video module network interface 595. In this manner, visual data received by the external network interface module 210G may be conveyed directly to the video input module 210C and then to the video receiver 800 (FIG. 8).

The external network interface module 210G may be configured according to some embodiments to enable remote control of the various functions for which soft buttons are included on the interface portion 350. For example, the interface portion 350 may include an IR receiver 545 for receiving commands using IrDA (Infrared Data Association) communications from an IR remote controller unit. Additionally or alternatively, the external network interface module 210G may be configured to enable control by means of a data processing system coupled to the external network interface module 210G by means of the external network interface 590. Thus, a data processing system (e.g., a teacher's computer, a smart phone, personal media player) may be utilized to control volume, audio and video source selection, etc. with a software application employed by the data processing system. Such a software application may also be utilized more broadly to control any of the various multimedia management modules 210 according to various embodiments of the present disclosure.

Additional multimedia management modules 210 may be employed according to various embodiments of multimedia management devices 110 of the disclosure. Another non-limiting example of a multimedia management module 210 may include a multimedia management module configured to enable wireless network connectivity. Such a multimedia management module 210 may be referred to herein as a wireless router module. The card portion 410 of a wireless router module may include circuitry configured to couple the wireless router module to an external network. According to various embodiments, the wireless router module may be coupled to an external network directly through one or more external network interfaces, or the wireless router module may be coupled to an external network through an external network interface module 210G. The card portion 410 of the wireless router module may further include circuitry configured to enable wireless transfer of packetized data between the wireless router module and one or more access terminals (e.g., computer, personal digital assistant, smartphone, electronic reader). By way of example and not limitation, the wireless router module may be configured to enable wireless transfer of packetized data through one or more of WiFi (IEEE 802.11), Bluetooth, WiMAX, or other conventional data communication protocols. In at least one embodiment, a wireless router module is configured to operate using WiFi protocols to enable wireless connectivity to an external network to one or more WiFi enabled access terminals.

Other multimedia management modules 210 may be configured as an RFID module adapted to enable tracking of inventory or other items in an area. For example an RFID module may be positioned near an entrance of an area 120 for identifying when an item enters and/or exits the area 120. In some embodiments, the RFID module may access or trigger an alarm if an item was removed from the area 120.

Another multimedia management module 210 may be configured as a tuner module adapted to receive television or cable broadcast signals and to enable channel changing at the tuner module itself or by means of a remote controller device.

A multimedia management module 210 may be configured as a panic alarm module adapted to communicate (e.g., by radio frequency) with a panic alarm switch (e.g., a key chain panic alarm) for accessing an audible and/or silent alarm.

Other multimedia management modules 210 may be adapted for controlling environmental and/or lighting controls. Such a multimedia management module 210 may include heat sensors and/or light sensors and may enable remote controlling of air conditioning and/or lighting for an area 120.

Yet additional multimedia management modules 210 may be configured to control volume automatically as a result of feedback from one or more sensors. For example, such a multimedia management module may include a circuitry for detecting and analyzing sound to noise ratios for a particular area 120, and may be adapted to automatically adjust volume to reduce or even eliminate sound bleeding between two or more adjacent areas 120, which would result in increased noise in an area 120.

Still other multimedia management modules 210 may be adapted to generate masking noise for a particular area 120 for the purpose of covering over or masking speech between two or more individuals. For example, in an area 120 where it may be desirable to mask communications between individuals from one or more bystanders or passersby, such a multimedia management module 210 may generate a signal tone with predetermined and/or adjustable curves to mask human speech. Such an area 120 may include a nurse's office or a pharmacy for masking communications of private medical information from being overheard from another person not privy to such information, or other areas in which private communications are important or necessary.

The various multimedia management modules 210 described above with reference to FIGS. 5A-5G are, therefore, merely intended to be examples of modules employable by various embodiments the multimedia management device 110 of the present disclosure. A person of ordinary skill in the art will recognize that more, fewer or different multimedia management modules 210 may be employed according to a variety of embodiments of the disclosure. Because the multimedia management device 110 of the present disclosure is capable of having multimedia management modules 210 added and removed to customize the multimedia management device 110 for the end user, any number of multimedia management modules 210 may be designed, developed or revised for any number of different functionalities. Additionally, two or more multimedia management modules 210 described herein may be combined into a single multimedia management module 210.

The various multimedia management modules 210 are communicatively coupled together to form an internal modular network, which may also be characterized herein as an intermodular network. Various means may be employed for interconnecting multimedia management modules 210 such as, for example, a backplane, wire, cable, etc. as well as combinations thereof, coupled between multimedia management modules 210. In at least some embodiments of the present disclosures, a multimedia management device 110 may employ one or more backplanes 310 and data transfer cables to facilitate such interconnectivity of the various multimedia management modules 210, as well as to facilitate the addition and removal of various multimedia management modules 210. FIG. 6A is a front view and FIG. 6B is a rear view of a backplane 310 according to at least one embodiment. The backplane 310 may comprise a rigid board, such as a printed circuit board, which may include circuitry, electronic devices or a combination thereof. The backplane 310 includes at least one module coupling feature 610 and at least one intermodular network interface 620.

The module coupling feature 610 is configured to be coupled to the backplane coupling feature 420 of a respective multimedia management module 210. In the embodiment shown in FIG. 6A, the backplane 310 comprises two module coupling features 610 and can, therefore, receive two multimedia management modules 210 coupled thereto. The two multimedia management modules 210 may be interconnected to each other by means of circuitry on or in the backplane 310 between the two module coupling features 610. In some embodiments, such as the embodiments described above in which the backplane coupling feature 420 comprises a plurality of pins, the module coupling feature 610 may comprise a plurality of slots into which a plurality of similarly configured pins may be disposed. The module coupling feature 610 enables multimedia management modules 210 to easily be electrically and mechanically installed and removed by simply inserting the backplane coupling feature 420 therein and simply removing the backplane coupling feature 420 therefrom. Thus, referring back to FIG. 3, with a backplane 310 disposed in the electrical gang box 320, a multimedia management module 210 may be installed at any time into the multimedia management device 110 simply by mechanically and electrically coupling the backplane coupling feature 420 to the module coupling feature 610.

Various multimedia management modules 210 may be coupled to different backplanes 310. To facilitate interconnectivity between multimedia management modules 210 on different backplanes 310, each backplane 310 may include one or more intermodular network interfaces 620, as shown in FIG. 6B. The intermodular network interface 620 may comprise any known interface for connecting a data transfer cable. By way of example and not limitation, the intermodular network interface 620 may comprise one of a RJ45, USB or FireWire connector. In the embodiment illustrated in FIG. 6B, the intermodular network interface 620 is disposed adjacent the rear side of the backplane 310.

Referring to both FIGS. 6A and 6B, a backplane 310 may further include one or more additional inputs and/or outputs. For example, at least one backplane may include a power input 630 for providing power to the multimedia management device 110. Only one backplane 310 of a plurality of backplanes need comprise the power input 630 for powering a multimedia management device 110 of the present disclosure. The backplanes 310 not comprising a power input 630 are configured to be powered by means of a data transfer cable coupled to the intermodular network interface 620 of the backplane 310 having the power input 630 and the backplanes 310 not having a power input 630. In other words, the multimedia management device 110 may be configured to include one powered backplane 310 coupled to a power supply through power input 630, and one or more additional backplanes 310 that receive power from the powered backplane 310 through the module network.

In yet other embodiments, however, power may be supplied to all of the backplanes 310 through one or more data transfer cables. For example, power may be supplied to the multimedia management device 110 from an external network using power over Ethernet (POE). In such an embodiment, an external network interface module 210G (FIG. 5G) may be employed, which is coupled to the external network and which receives power through the external network interface 590 (FIG. 5G).

A backplane 310 may also include one or more speaker outputs 640 for directly coupling the multimedia management device 110 to one or more audio transducers. A backplane 310 may further include a master override input 650 for enabling cut-out controls. The master override input 650 enables the multimedia management device 110 to mute sound being distributed to the audio transducers, as well as stop video when a master sound system is activated. Furthermore, the master override input 650 enable input from an external source. For example, the master override input 650 may be coupled to an external system, such as a school-wide PA system or emergency system. The external system may be used to make school-wide announcements such as, for example, daily informational announcement, mass notifications, code red or code blue emergency conditions (i.e., medical emergency), etc. When the external system is activated, the multimedia management device 110 is configured to mute the sound from other inputs, such as the audio input module, and to open an audio path to enable the external system to broadcast another announcement (e.g., mass notification, code reds, code blues).

A backplane 310 may include one or more emergency override inputs 660, according to one or more embodiments, enabling cut-out controls when an emergency system is activated. For example, the emergency override inputs 660 may be coupled to one or more emergency evacuation systems, such as a fire alarm. When the emergency evacuation system is activated, a signal is received through the one or more emergency override inputs 660 and the multimedia management device 110 may mute sound and/or stop video until the emergency evacuation system is deactivated.

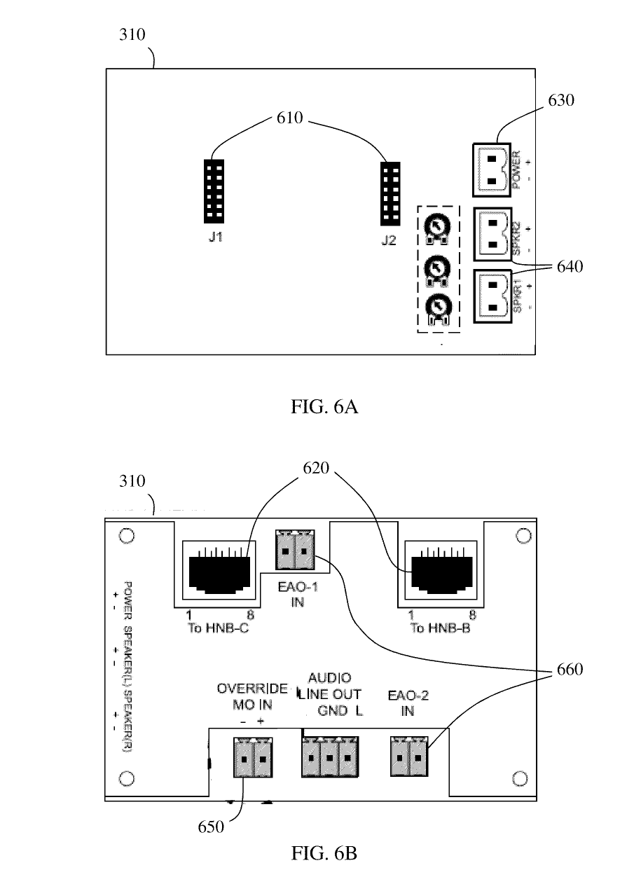

As noted above, in embodiments employing one or more backplanes 310, the backplane 310 may include circuitry thereon or therein. FIGS. 7A-7C illustrate some embodiments of backplanes 310 of the present disclosure showing block diagrams representing circuitry which may be employed in a backplane 310. The backplane 310A shown in FIG. 7A may be configured to receive a volume control module 210A in the right module coupling feature 610, labeled J2, and one of an audio input module 210B, a remote control module 210D, or an external network module 210G in the left module coupling feature 610, labeled J1. Power is supplied to each of the multimedia management modules 210 through the power input 630 or via the intermodular network interface 620. That is, once power in backplane 310 has been coupled to power via the power input 630, other backplanes and/or modules may be powered via the intermodular network interface 620.

The volume control module 210A in module coupling feature labeled J2 is electrically coupled with whichever of the audio input module 210B or remote control module 210D is received in module coupling feature labeled J1. The volume control module 210A is further coupled to left and right sets of audio transducers through speaker outputs 640. If, for example, the audio input module 210B is received in the module coupling feature labeled J1, any audio input through the audio input module 210B is directed through circuitry to the volume control module 210A, from which the audio is directed to the audio transducers coupled to speaker outputs 640.

The backplane 310A is electrically coupled to backplanes 310B and 310C of FIGS. 7A and 7B, respectively, with a data transfer cable 710 coupled to the intermodular network interface 620. The backplane 310B, shown in FIG. 7B, is configured to receive an audio input module 210B in the left module coupling feature 610, labeled J1, and a video input module 210C (indicated by dashed lines) in the right module coupling feature 610, labeled J2. As illustrated, an audio input module 210B received in the left module coupling feature 610, labeled J1, is electrically coupled to the intermodular network interface 620. Thus, audio received through the audio input module 210B may be communicated from the audio input module 210B to a remote control module 210D received in the left module coupling feature 610, labeled J1, on the backplane 310A. The received audio can then be communicated from the remote control module 210D to the volume control module 210A and then to the audio transducers coupled to speaker outputs 640.

The video input module 210C received in the right module coupling feature 610, labeled J2, is also electrically coupled to the intermodular network interface 620. Accordingly, the video input module 210C may receive input image data from the video inputs 535 (FIG. 5C) and transmit the input image data to other modules of the intermodular network, such as the external network module 210G. Similarly, the video input module 210C may receive image data from the intermodular network to be distributed to one or more display devices for display. As shown in FIG. 7B, and as discussed above with reference to FIG. 5C, the video input module 210C includes a video network interface 540 coupled to a video receiver 800 (FIG. 8), which is coupled to one or more display devices. Thus, any image data received by either the video inputs 535 (FIG. 5C) or from the intermodular network may be distributed to and displayed by one or more display devices.

The backplane 310C shown in FIG. 7C is configured to receive a radio frequency receiver module 210E in the left module coupling feature 610, labeled J1, and a radio frequency transmitter module 210F in the right module coupling feature 610, labeled J2. As illustrated, both the left and right module coupling features 610 are electrically coupled to an intermodular network interface 620 so that both the radio frequency receiver module 210E and the radio frequency transmitter module 210F are coupled to the intermodular network. In operation, audio data received by the radio frequency receiver module 210E can be communicated to the audio input module 210B and/or the volume control module 210A, and ultimately communicated to the audio transducers coupled to speaker outputs 640 and/or an external network via an external network interface module 210G. Similarly, audio data that is input through the audio input module 210B, the radio frequency receiver module 210E, and/or the external network interface module 210G may be communicated to the radio frequency transmitter module 210F to be transmitted to one or more receivers.

It is noted that neither of backplanes 310B and 310C include any power inputs 630. Instead, as has been described herein above, both backplanes 310B and 310C are configured to obtain power from the backplane 310A via a data transfer cable coupled between the intermodular network interfaces 620 of each backplane 310.

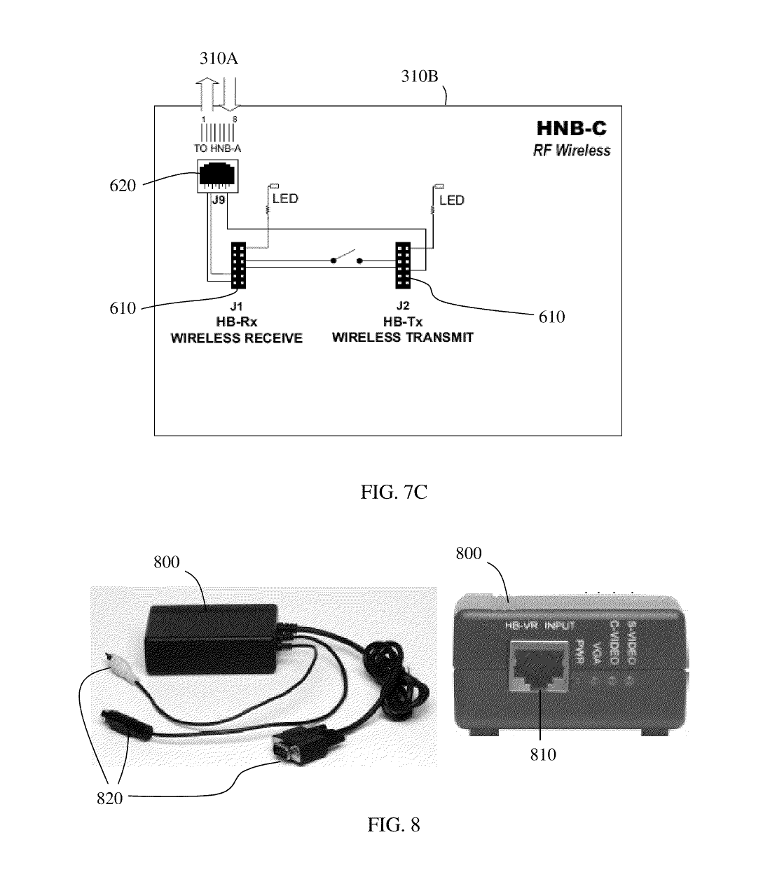

Some embodiments of the present disclosure are directed to methods of assembling a multimedia management device. FIG. 9 illustrates a flow diagram for a method 900 of assembling a multimedia management device 110 according to at least one embodiment. Referring to both FIG. 3 and FIG. 9, the method 900 may generally include disposing at step 910 two or more multimedia management modules 210 at least partially into an electrical gang box 320, and interconnecting at step 920 the multimedia management modules 210 to enable communication among each of the multimedia management modules 210.

In at least some embodiments, the multimedia management modules 210 may be disposed into the electrical gang box 320 by mechanically coupling the interface portion 350 of each multimedia management module 210 to the electrical gang box 320. For example, a fastener may be disposed in apertures 360 of the multimedia management modules 210, as well as disposed in apertures 370 of the electrical gang box 320. In at least some embodiments, a backplane 310 is disposed into the electrical gang box 320. As noted above, the backplane 310 may be mechanically coupled to a bracket 380, and the bracket 380 and backplane 310 are disposed within the electrical gang box 320.

The multimedia management modules 210 may be interconnected in some embodiments by electrically coupling the multimedia management modules 210 to the backplane 310. For example, the backplane coupling feature 410 (FIG. 4) may be electrically coupled to the module coupling feature 610. As noted above, some embodiments of a backplane 310 include two or more module coupling features 610. When a multimedia management module 210 is electrically coupled to each of the two or more module coupling features 610 of the same backplane 310, the multimedia management modules 210 may be electrically coupled to each other via electrical circuitry disposed on and/or in the backplane 310. In other embodiments, a plurality of backplanes may be employed with one or more multimedia management modules 210 coupled thereto. In such embodiments, as noted herein above, a data transfer cable may be coupled to the intermodular network interface 620 of each backplane 310, resulting in the electrical connection of each backplane 310 as well as the interconnection of the multimedia management modules 210 on each backplane 310.

Because the backplanes 310 and the multimedia management modules 210 are so easily installed (and similarly removed), each backplane 310 and/or multimedia management module 210 may be readily replaced by one or more new backplanes 310 or multimedia management modules 210, respectively. Accordingly, each backplane 310 or multimedia management module 210 may be replaced with a repaired, upgraded or different version thereof.

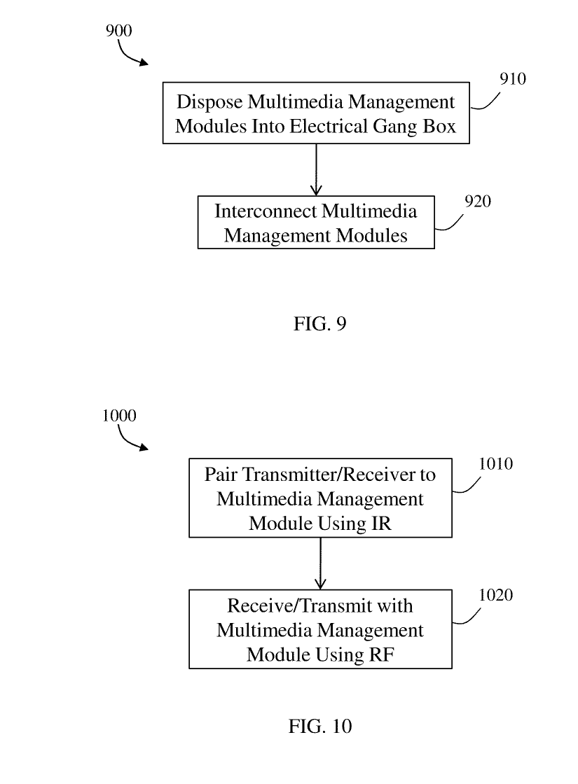

Further embodiments of the present disclosure include operational methods of a multimedia management device. FIG. 10 illustrates a flow diagram for an embodiment of an operational method 1000 of a multimedia management device 110 including a radio frequency receiver module 210E, a radio frequency transmitter module 210F, or both. The method 1000 includes the steps of pairing 1010 a transmitter or receiver to a multimedia management device 210 using infrared communications, and receiving or transmitting 1020 with the multimedia management module 210 using a radio frequency band.

By way of example and not limitation, and with reference to FIG. 5E, a microphone may be paired to a radio frequency receiver module 210E by pressing a pairing button 570 associated with an IR sensor 575 of the radio frequency receiver module 210E, and pressing a pairing button associated with the microphone. The IR sensor 575 of the radio frequency receiver module 210E and a similar IR sensor on the microphone are directed toward each other, and the radio frequency receiver module 210E and microphone communicate via IrDA. Using the infrared communications, the radio frequency receiver module 210E and microphone establish a connection over a first radio frequency band. Establishing a connection (i.e., pairing) may include identifying one or more channels of the radio frequency band and establishing a connection on the one or more identified channels. In addition, establishing the connection may also include identifying and agreeing to a channel hopping scheme on the respective radio frequency band.

After the radio frequency receiver module 210E and the microphone have established a connection over the first radio frequency band (i.e., are paired), the microphone begins wireless data transmission using the respective radio frequency band and the radio frequency receiver module 210E begins receiving the wireless data transmission.

Furthermore, a second microphone may be paired to the radio frequency receiver module 210E in a similar manner. However, because the radio frequency receiver module 210E is configured to receive wireless communications over a plurality of frequency bands, the second microphone may be paired to the radio frequency receiver module 210E to establish communications over a second radio frequency band, enabling use of both microphones simultaneously.

By way of another example and not limitation, and with reference to FIG. 5F, a student receiver configured to receive personal headphones may be paired to a radio frequency transmitter module 210F in a similar manner as the pairing of the microphone to the radio frequency receiver module 210E. In particular, a pairing button 570 associated with an IR sensor 575 of the radio frequency transmitter module 210F is pressed, as well as a pairing button associated with the student receiver. The IR sensor 575 of the radio frequency transmitter module 210F and a similar IR sensor on the receiver are directed toward each other, and the radio frequency transmitter module 210F and student receiver communicate via IrDA. Using the infrared communications, the radio frequency transmitter module 210F and student receiver establish a connection over a first radio frequency band. Establishing a connection (i.e., pairing) may include identifying one or more channels of the radio frequency band and establishing a connection on the one or more identified channels. In addition, establishing the connection may also include identifying and agreeing to a channel hopping scheme on the respective radio frequency band.

After the radio frequency transmitter module 210F and the student receiver have established a connection over the first radio frequency band (i.e., are paired), the radio frequency transmitter module 210F begins wireless data transmission using the respective radio frequency band and the student receiver begins receiving the wireless data transmission.

Furthermore, according to some embodiments of the present disclosure, the second radio frequency band may be employed by the radio frequency transmitter module 210F to simultaneously transmit audio data that is different from the data transmitted over the first radio frequency band by the radio frequency transmitter module 210F. In this manner, a student receiver may select between the first radio frequency band for a first stream of audio data, or the second radio frequency band for a second, different stream of audio data. Such embodiments may be employed, for example, for simultaneous transmission of the original audio data to the hearing impaired and translation audio data to foreign language speakers.

While certain exemplary embodiments have been described and shown in the accompanying drawings, it is to be understood that such embodiments are merely illustrative of and not restrictive on the broad disclosure, and that this disclosure not be limited to the specific constructions and arrangements shown and described, since various other additions and modification to, and deletions from, the described embodiments will be apparent to one of ordinary skill in the art. Thus, the scope of the disclosure is only limited by the literal language, and legal equivalents, of the claims which follow.

What is claimed is:

1. A multimedia management device, comprising:
a plurality of media management modules coupled together in an intermodular network, at least some of the media management modules of the plurality of media management modules adapted to distribute at least one of audio or video within an area;
wherein each media management module of the plurality of media management modules is configured to enable a distinct functionality; and
wherein each media management module of the plurality of media management modules is sized and configured to be disposed at least partially within an electrical gang box.

2. The multimedia management device of claim 1, wherein each media management module of the plurality of media management modules comprises an interface portion, and a card portion including a backplane coupling feature.

3. The multimedia management device of claim 2, wherein the interface portion is sized and configured to be mechanically coupled to an electrical gang box.

4. The multimedia management device of claim 2, further comprising at least one backplane, the backplane including a module coupling feature coupled to the backplane coupling feature of at least one media management module of the plurality of media management modules, wherein the at least one media management module is coupled to the other media management modules through the backplane.

5. The multimedia management device of claim 4, wherein the backplane includes electrical circuitry and an intermodular network interface, and wherein the at least one media management module is coupled to the other media management modules through at least one of the electrical circuitry or the intermodular network interface.

6. The multimedia management device of claim 4, wherein the at least one backplane is sized and configured to be disposed within a standard electrical gang box.

7. The multimedia management device of claim 4, wherein the backplane coupling feature of the at least one media management module is adapted to be:
decoupled from the module coupling feature of the at least one backplane; and
coupled to a module coupling feature of another, different backplane.

8. The multimedia management device of claim 4, wherein the module coupling feature of the at least one backplane is adapted to be:
decoupled from the backplane coupling feature of the at least one media management module; and
coupled to a backplane coupling feature of another, different media management module.

9. The multimedia management device of claim 1, further configured to:
receive at least one additional media management module coupled to the intermodular network; and
decouple at least one media management module of the plurality of media management modules from the intermodular network.

10. The multimedia management device of claim 1, wherein the plurality of media management modules includes media management modules selected from the group of media management modules including a volume control module, an audio input module, a video input module, an remote control module, a radio frequency receiver module, a radio frequency transmitter module or an external network interface module.

11. The multimedia management device of claim 1, wherein a media management module of the plurality of media management modules comprises an audio input module, the audio input module including at least one of an audio input, a volume control, a sound shaping control, or an audio source selector.

12. The multimedia management device of claim 1, wherein a media management module of the plurality of media management modules comprises a video input module, the video input module including at least one of a video input or a video network interface.

13. The multimedia management device of claim 1, wherein a media management module of the plurality of media management modules comprises a radio frequency receiver module, the radio frequency receiver module including:
at least one infrared (IR) sensor configured to communicate with a transmitter for pairing the transmitter to the radio frequency receiver module; and
a plurality of receivers, each receiver configured to receive wireless communications on a different frequency band.

14. The multimedia management device of claim 1, wherein a media management module of the plurality of media management modules comprises a radio frequency transmitter module, the radio frequency transmitter module including:
an infrared (IR) sensor configured to communicate with a plurality of receivers for pairing each receiver of the plurality of receivers to the radio frequency transmitter module; and
a transmitter configured to transmit wireless data to the plurality of receivers on at least one radio frequency band.

15. The multimedia management device of claim 1, wherein a media management module of the plurality of media management modules comprises an external network interface module, the external network interface module including an external network interface configured to couple the external network interface module to an external network.

16. The multimedia management device of claim 15, wherein the external network interface module is individually addressable by an external network to which it is coupled.

17. The multimedia management device of claim 15, wherein the external network interface module is adapted to receive a data stream intended for the external network interface module from among a plurality of data streams intended for a plurality of different end-locations on the external network.

18. The multimedia management device of claim 15, wherein the external network interface module is configured to convey data from the external network interface module to a remote location using the external network.

19. The multimedia management device of claim 1, wherein a media management module of the plurality of media management modules comprises a wireless router module, the wireless router module coupled to an external network and adapted to enable wireless network connectivity to the external network for one or more access terminals.

20. The multimedia management device of claim 19, wherein the wireless router module is coupled to the external network through a media management module configured as an external network interface module.

21. The multimedia management device of claim 19, wherein the wireless router module is configured to enable wireless network connectivity using WiFi protocols to enable wireless network connectivity to the external network for one or more WiFi enabled access terminals.

22. The multimedia management device of claim 1, wherein at least some media management modules of the plurality of media management modules are powered via the intermodular network.

23. The multimedia management device of claim 1, wherein the plurality of media management modules are powered via a single external power supply.

24. A multimedia management device, comprising:
a backplane sized and configured to be disposed within an electrical gang box, the backplane including at least one module coupling feature and at least one intermodular network interface;
at least one media management module including an interface portion sized and configured to be mechanically coupled to an electrical gang box, and a card portion including a backplane coupling feature mechanically and electrically coupled to the at least one module coupling feature of the backplane.

25. The multimedia management device of claim 24, further comprising a bracket sized and configured to be disposed in and mechanically coupled to an electrical gang box, the bracket comprising a rear plate mechanically coupled to the backplane and a plurality of front flanges mechanically coupled to the interface portion of the at least one media management module.

26. The multimedia management device of claim 24, wherein the at least one media management module is selected from a group of media management modules including a volume control module, an audio input module, a video input module, a remote control module, a radio frequency receiver module, a radio frequency transmitter module or an external network interface module.

27. The multimedia management device of claim 26, wherein the at least one media management module comprises at least one of the radio frequency receiver module or the radio frequency transmitter module, and wherein the card portion comprises a plurality of antennas sized and configured to be at least substantially enclosed between the backplane and the interface portion.

28. A multimedia management assembly, comprising:
an electrical gang box; and
a plurality of media management modules, each media management module of the plurality of media management modules including an interface portion coupled to the electrical gang box, and a card portion extending into the electrical gang box;
wherein the plurality of media management modules are communicatively coupled together; and
wherein each media management module of the plurality of media management modules is configured to be independently removable from the assembly without disabling the functionality of a remaining media management module.

29. The multimedia management assembly of claim 28, wherein the gang box comprises one of a one-gang, two-gang, three-gang, four-gang, five-gang or six-gang electrical gang box.

30. The multimedia management assembly of claim 28, further comprising:
at least one backplane disposed within the gang box and including at least one intermodular network interface and at least one module coupling feature;
wherein the at least one module coupling feature of the backplane is mechanically and electrically coupled to a backplane coupling feature on a card portion of a media management module of the plurality of media management modules.

31. The multimedia management assembly of claim 30, further comprising a bracket disposed at least partially within the electrical gang box, wherein at least some media management modules of the plurality of media management modules and the at least one backplane are mechanically coupled to the bracket.

32. A multimedia management device, comprising:
a multimedia management module pluggable into an intermodular network disposed at least partially within an electrical gang box, the multimedia management module configured as a radio frequency receiver module, wherein the radio frequency receiver module is adapted to:
pair to a radio frequency transmitter using infrared to communicate pairing information between the radio frequency transmitter and the radio frequency receiver module; and
receive audio data transmitted from the paired radio frequency transmitter using a first radio frequency band.

33. The multimedia management device of claim 32, wherein the radio frequency receiver module is further adapted to:
pair to another radio frequency transmitter using infrared to communicate pairing information between the other radio frequency transmitter and the radio frequency receiver module; and
simultaneously receive audio data transmitted from the other paired radio frequency transmitter using a second radio frequency band.

34. The multimedia management device of claim 32, wherein the radio frequency receiver module is adapted to pair to the radio frequency transmitter using infrared to:
identify at least one channel of the first radio frequency band available for communications; and
establish a connection between the radio frequency transmitter and the radio frequency receiver module on the at least one identified channel.

35. The multimedia management device of claim 32, wherein the radio frequency receiver module is adapted to pair to the radio frequency transmitter using infrared to:
identify a plurality of channels of the first radio frequency band available for communications; and
identify a channel hopping scheme for the first radio frequency band.

36. The multimedia management device of claim 32, wherein the radio frequency receiver module is adapted to pair to a radio frequency transmitter configured as a microphone using infrared to communicate between the microphone and the radio frequency receiver module.

37. A multimedia management device, comprising:
a multimedia management module pluggable into an intermodular network disposed at least partially within an electrical gang box, the multimedia management module configured as a radio frequency transmitter module, wherein the radio frequency transmitter module is adapted to:
pair to a radio frequency receiver using infrared to communicate between the radio frequency receiver and the radio frequency transmitter module; and
transmit audio data to the radio frequency receiver using a first radio frequency band.

38. The multimedia management device of claim 37, wherein the radio frequency transmitter module is further adapted to simultaneously transmit audio data using one or more additional frequency band.

39. The multimedia management device of claim 37, wherein the radio frequency transmitter module is adapted to pair to the radio frequency receiver using infrared to:
identify at least one channel of the first radio frequency band available for communications; and
identify a channel hopping scheme for communicating using the first radio frequency band.
